(19) United States
(12) Patent Application Publication
(10) Pub. No.: US 2025/0021027 A1
(43) Pub. Date: Jan. 16, 2025

(54) EDGE EXPOSURE APPARATUS AND EDGE EXPOSURE METHOD

(71) Applicant: Tokyo Electron Limited, Tokyo (JP)

(72) Inventors: Keisaku KAI, Koshi City (JP); Masaru TOMONO, Koshi City (JP); Seiichi KURE, Koshi City (JP); Yukinobu MIYAMOTO, Koshi City (JP)

(73) Assignee: Tokyo Electron Limited, Tokyo (JP)

(21) Appl. No.: 18/771,025

(22) Filed: Jul. 12, 2024

(30) Foreign Application Priority Data
Jul. 13, 2023 (JP) 2023-115470
Apr. 25, 2024 (JP) 2024-071816

(51) Int. Cl. G03F 7/00; G03F 7/20

(52) U.S. Cl. CPC G03F 7/70933; G03F 7/2022; G03F 7/70525

(57) ABSTRACT

An edge exposure apparatus includes a substrate holder configured to hold and rotate a substrate; an exposure device for radiating exposure light toward a peripheral region of a front surface of the substrate held by the substrate holder; and an exhaust including an exhaust range for performing exhaust and in an outside of an edge of the substrate held by the substrate holder, a place corresponding to a radiation position of the exposure device and extending along the edge.

### CROSS-REFERENCE TO RELATED APPLICATIONS

This application claims the benefit of Japanese Patent Application Nos. 2023-115470 and 2024-071816 filed on Jul. 13, 2023 and Apr. 25, 2024, respectively the entire disclosures of each are incorporated herein by reference.

### TECHNICAL FIELD

The exemplary embodiments described herein pertain generally to an edge exposure apparatus and an edge exposure method.

### BACKGROUND

Patent Document 1 discloses a substrate processing apparatus configured to perform a predetermined substrate processing including at least one of an edge exposure processing for exposing an edge portion of a substrate and a substrate inspection processing for inspecting the substrate.

### PRIOR ART DOCUMENT

Patent Document 1: Japanese Patent Laid-open Publication No. 2012-222086

### SUMMARY

An edge exposure apparatus includes a substrate holder configured to hold and rotate a substrate; an exposure device configured to radiate exposure light toward a peripheral region of a front surface of the substrate held by the substrate holder; and an exhaust device configured to perform exhaust from an exhaust range including, in an outside of an edge of the substrate held by the substrate holder, a place corresponding to a radiation position of the exposure device and extending along the edge.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a schematic plan view illustrating an example of a substrate processing apparatus;

FIG. 2 is a schematic side view illustrating the example of the substrate processing apparatus;

FIG. 3 is a schematic side view illustrating an example of an edge exposure apparatus;

FIG. 4 is a schematic plan view illustrating the example of the edge exposure apparatus;

FIG. 5A and FIG. 5B are schematic views illustrating an example of an exposure device in the edge exposure apparatus;

FIG. 6 is a schematic view illustrating an example of a lower exhaust device of the edge exposure apparatus;

FIG. 7A and FIG. 7B are schematic views illustrating an example of an outer peripheral exhaust device of the edge exposure apparatus;

FIG. 8A and FIG. 8B are schematic views illustrating an example of a collection member of the outer peripheral exhaust device;

FIG. 9A and FIG. 9B are schematic views illustrating an example of a gas discharger of the edge exposure apparatus;

FIG. 10 is a block diagram illustrating an example of a hardware structure of a controller of the edge exposure apparatus;

FIG. 11 is a flowchart illustrating an example of an edge exposure method;

FIG. 12 is a schematic view illustrating an example of an outer peripheral exhaust device of the edge exposure apparatus;

FIG. 13 illustrates an example of a substrate in which a notch portion is formed;

FIG. 14A and FIG. 14B are schematic views illustrating an example of an outer peripheral exhaust device of the edge exposure apparatus;

FIG. 15 is a schematic view illustrating an example of an outer peripheral exhaust device of the edge exposure apparatus;

FIG. 16 is a schematic view illustrating an example of a collection member of the outer peripheral exhaust device;

FIG. 17 is a schematic view illustrating an example of a connection structure between the collection member and a suction member; and

FIG. 18 is a schematic view illustrating an example of a distribution of flow rates from a gas discharger.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, a wafer processing system will be described as a substrate processing apparatus according to the present exemplary embodiment with reference to the accompanying drawings. In the specification, components having substantially the same function and configuration will be denoted with the same reference numeral, and redundant description thereof will be omitted. In some drawings, there is shown an orthogonal coordinate system defined by X-, Y- and Z-axes. In the following exemplary embodiments, the Z-axis corresponds to a vertical direction and the X-axis and the Y-axis correspond to a horizontal direction.

### Wafer Processing System

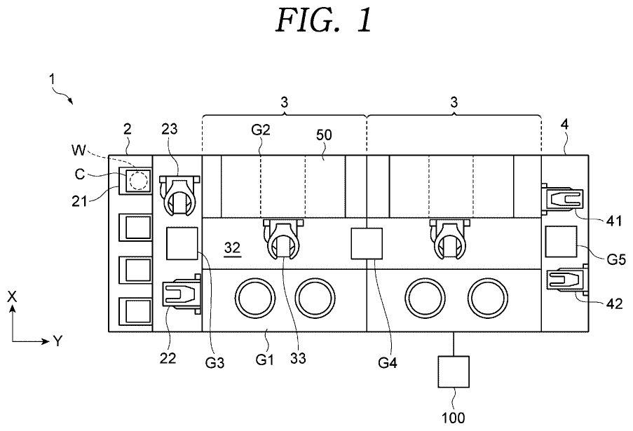

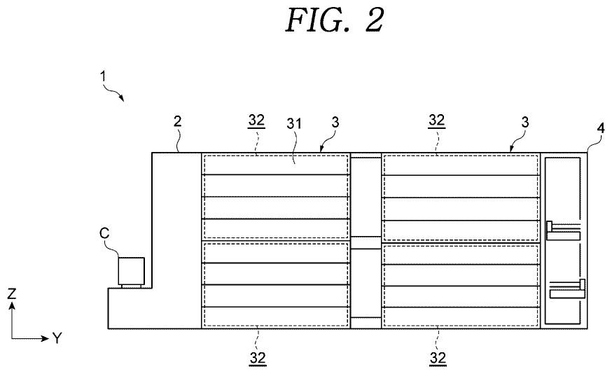

First, a configuration of a wafer processing system according to the present exemplary embodiment will be described. FIG. 1 and FIG. 2 are schematic plan view and side view, respectively, illustrating a configuration of a wafer processing system 1. In the present exemplary embodiment, the wafer processing system 1 will be described as a photolithography processing system configured to perform a processing of forming a resist film on a wafer W (substrate) and a processing of developing the resist film.

The wafer processing system 1 includes, as shown in FIG. 1, a cassette station 2 into/out of which a cassette C accommodating a plurality of wafers W is transferred, and a processing station 3 equipped with a plurality of various processing apparatuses configured to perform predetermined processes on the wafer W. The wafer processing system 1 has a configuration in which the cassette station 2, the processing station 3, and an interface station 4 configured to deliver the wafer W to/from an exposure apparatus (not shown) adjacent to the interface station 4 on the opposite side to the processing station 3 are integrally connected. Further, as shown in FIG. 1, two processing stations 3 are provided between the cassette station 2 and the interface station 4. However, one processing station 3 or three or more processing stations 3 may be provided.

The cassette station 2 is equipped with a plurality of cassette placing tables 21 and wafer transfer devices 22 and 23. In the cassette station 2, the wafer transfer device 22 or 23 is configured to transfer the wafer W between the cassette C placed on the placing table 21 and the processing station 3. For this reason, each of the wafer transfer devices 22 and 23 is equipped with a driving mechanism movable in an X-axis direction, a Y-axis direction and a vertical direction and around a vertical axis (in a θ-direction) as necessary, or may be equipped with a driving mechanism movable in all directions.

At least one of the wafer transfer devices 22 and 23 can deliver the wafer W to/from the cassette C, and can also perform a delivery operation of the wafer W with respect to the processing station 3. The delivery operation of the wafer W with respect to the processing station 3 refers to, for example, delivery of the wafer W with respect to a third block G3 equipped with a transit apparatus that can be accessed by a wafer transfer device 33, which will be described later, within the processing station 3. The third block G3 may be equipped with a plurality of transit apparatuses (not shown) arranged in the vertical direction.

Also, the third block G3 may be equipped with an inspection apparatus (not shown) configured to perform inspection on the wafer W at a position accessible by any one of the wafer transfer devices 22 and 23.

The processing station 3 is provided with a plurality of blocks, for example, three blocks including first, second and fourth blocks G1, G2 and G4. Also, as shown in FIG. 2, a plurality of layers 31 including the first and second blocks G1 and G2 is stacked in the vertical direction. For example, the first block G1 is provided at a front surface side of the processing station 3 (in the negative X-axis direction in FIG. 1) and the second block G2 is provided at a rear surface side of the processing station 3 (in the positive X-axis direction in FIG. 1). The fourth block G4 is provided at the side of the interface station 4 of the processing station 3 (in the positive Y-axis direction in FIG. 1) or at a connection portion with another adjacent processing station 3. The fourth block G4 may be equipped with a plurality of transit apparatuses arranged in the vertical direction. Also, the above-described third block G3 may be provided within the processing station 3.

In the first block G1, a plurality of processing apparatuses, such as a patterning film forming apparatus and a developing apparatus all of which are not illustrated, is arranged. The patterning film forming apparatus may include, for example, a resist film forming apparatus and an anti-reflection film forming apparatus.

For example, the plurality of processing apparatuses is arranged in a horizontal direction. Also, the numbers, arrangement and types of these apparatus can be selected as required.

For example, in the patterning film forming apparatus and the developing apparatus, a predetermined processing liquid or a predetermined gas is supplied onto the wafer W. Accordingly, in the patterning film forming apparatus, a resist film as a mask for forming a pattern of a film on a lower layer side is formed or an anti-reflection film for efficiently performing a light radiation processing, such as an exposure processing, is formed. Further, in the developing apparatus, the mask is formed into a concave and convex shape by removing a part of the exposed resist film.

For example, in the second block G2, thermal treatment apparatuses (not shown) configured to perform thermal treatments, such as heating and cooling, on the wafer W are arranged and provided in the vertical direction and in the horizontal direction. Further, in the second block G2, a hydrophobizing apparatus (not shown) configured to perform hydrophobization for enhancing fixedness between a resist liquid and the wafer W and an edge exposure apparatus 50 configured to expose an outer peripheral portion of the wafer W are arranged and provided in the vertical direction (in the Z-axis direction in FIG. 2) and in the horizontal direction. The numbers and arrangement of the thermal treatment apparatuses, the hydrophobizing apparatus and the edge exposure apparatus 50 can be selected as required.

As shown in FIG. 1, when viewed from the top, a wafer transfer region 32 is formed between the first block G1 and the second block G2. For example, a wafer transfer device 33 is provided in the wafer transfer region 32.

The wafer transfer device 33 has a transfer arm movable, for example, in the Y-axis direction, a forward/backward direction, the θ-direction, and the vertical direction. The transfer arm of the wafer transfer device 33 can move within the wafer transfer region 32 to transfer the wafer W to a predetermined apparatus within the first block G1, the second block G2, the third block G3, and the fourth block G4 around the wafer transfer device 33. As shown in FIG. 1, the processing station 3 is plural in number. In this case, the wafer transfer device 33 provided in the processing station 3 located at the side of the interface station 4 can transfer the wafer W to a predetermined apparatus within a fifth block G5, which will be described later, in addition to the first, second and fourth blocks G1, G2 and G4.

For example, a plurality of wafer transfer devices 33 is provided in the vertical direction as shown in FIG. 2. One of the wafer transfer devices 33 can transfer the wafer W to a predetermined apparatus located at a height position of a plurality of upper layers 31 among a plurality of layers 31 stacked in the vertical direction. Also, another wafer transfer device 33 can transfer the wafer W to a predetermined apparatus located at a height position of multiple lower layers 31 disposed under the plurality of upper layers 31. A plurality of wafer transfer regions 32 is provided to transfer the wafer W as described above. Further, the wafer transfer device 33 may be provided for each layer 31. As such, the number of wafer transfer devices 33 and the number of layers 31 corresponding to each wafer transfer device 33 can be selected as required.

In the wafer transfer region 32, the first block G1 or the second block G2, a shuttle transfer apparatus (not shown) may be provided. The shuttle transfer apparatus is configured to linearly transfer the wafer W between a space adjacent to one side of the processing station 3 and another space adjacent to the other side.

The interface station 4 is provided with the fifth block G5 equipped with a plurality of transit apparatuses, and wafer transfer devices 41 and 42. In the interface station 4, the wafer transfer device 41 or 42 is configured to transfer the wafer W between the fifth block G5 to and from which the wafer W is delivered by the wafer transfer device 33 and the exposure apparatus. For this reason, each of the wafer transfer devices 41 and 42 is equipped with a driving mechanism movable in the X-axis direction, the Y-axis direction and the vertical direction and about the vertical axis (in the θ-direction) as necessary, or may be equipped with a driving mechanism movable in all directions. At least one of the wafer transfer devices 41 and 42 can support and transfer the wafer W between the transit apparatus within the fifth block G5 and the exposure apparatus.

A cleaning apparatus configured to clean a front surface of the wafer W and the above-described edge exposure apparatus 50 may be provided at a position accessible by any one of the wafer transfer devices 41 and 42 within the interface station 4.

The inspection apparatus may be provided in the cassette station 2 as described above. Alternatively, the processing station 3 and the interface station 4 may be provided with the inspection apparatus at a position accessible by any one of the transfer arms (33, 41 and 42 in FIG. 1 or FIG. 2) in the processing station 3 and the interface station 4. The edge exposure apparatus 50 may function to expose the wafer W, and also function to inspect the wafer W.

The wafer processing system 1 is provided with a control device 100. The control device 100 is, for example, a computer and has a program storage (not shown). The program storage stores a program for controlling the processes on the wafer W in the wafer processing system 1. Also, the program storage stores a program for executing the processes on the wafer W in the wafer processing system 1 by controlling the operations of a driving system, such as the above-described various processing apparatuses and transfer devices. The above-described programs are recorded on a computer-readable recording medium H, and may be installed into the control device 100 from the recording medium H.

### Operation of Wafer Processing System

The wafer processing system 1 is configured as described above. Hereinafter, an example of a wafer processing performed by the wafer processing system 1 configured as described above will be described.

First, the cassette C accommodating the wafers W is carried into the cassette station 2 of the wafer processing system 1 to be placed on the cassette placing table 21. Then, each of the wafers W in the cassette C is successively taken out by the wafer transfer device 22 or 23 and transferred to the transit apparatus in the third block G3.

The wafer W transferred to the transit apparatus in the third block G3 is supported and transferred by the wafer transfer device 33 to the hydrophobizing apparatus in the second block G2, and subjected to hydrophobization. Then, the wafer W is transferred by the wafer transfer device 33 to the resist film forming apparatus, and the resist film is formed on the wafer W. Thereafter, the wafer W is transferred to the thermal treatment apparatus and subjected to pre-baking. The pre-baked wafer W is transferred to the transit apparatus in the fifth block G5. If the processing station 3 is plural in number as shown in FIG. 1 and FIG. 2, the wafer W may be placed on the transit apparatus in the fourth block G4 before being transferred to the transit apparatus in the fifth block G5, and then delivered to and from the plurality of wafer transfer devices 33. Also, the wafer W is transferred by the wafer transfer device 33 to the edge exposure apparatus 50, and the outer peripheral portion of the wafer W is exposed.

The wafer W transferred to the transit apparatus in the fifth block G5 is transferred by the wafer transfer devices 41 and 42 to the exposure apparatus and subjected to an exposure processing in a predetermined pattern. Before the exposure processing, the wafer W may be cleaned by the cleaning apparatus.

The wafer W exposed by the exposure apparatus is transferred by the wafer transfer devices 41 and 42 to the transit apparatus in the fifth block G5. Then, the wafer W is transferred by the wafer transfer device 33 to the thermal treatment apparatus and subjected to post-exposure baking.

The post-exposure baked wafer W is transferred by the wafer transfer device 33 to the developing apparatus and subjected to the development processing. After the development processing, the wafer W is transferred by the wafer transfer device 33 to a thermal treatment apparatus 40 and subjected to post-baking.

Thereafter, the wafer W is transferred by the wafer transfer device 33 to the transit apparatus in the third block G3 and then transferred by the wafer transfer device 22 or 23 of the cassette station 2 to a predetermined cassette C of the cassette placing table 21. Thus, the series of photolithography processing are ended.

The wafer processing system of the present disclosure is not limited to the above-described configuration and operation. For example, it has been described in the above-described exemplary embodiment that the wafer W is delivered between the interface station 4 and the exposure apparatus. However, the wafer processing system may not be directly connected to the exposure apparatus. In this case, for example, the wafer W may be transferred from the cassette station 2 to the processing station 3 and subjected to a necessary processing, and then may be returned to the cassette station 2 so as to be transferred to the outside. Also, an unnecessary one of the exemplified processing apparatuses may not be provided or may not perform a corresponding processing.

### Edge Exposure Apparatus

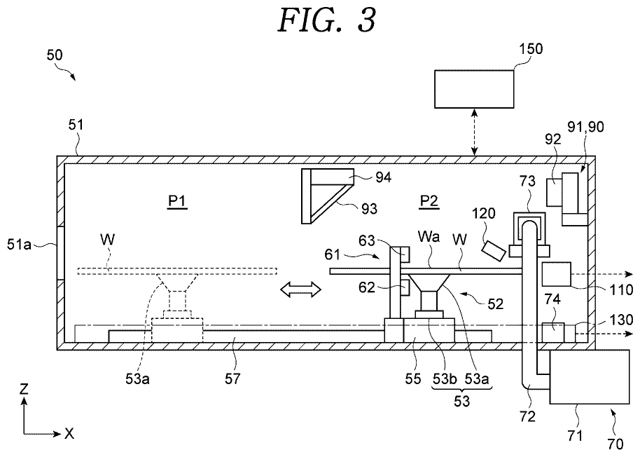

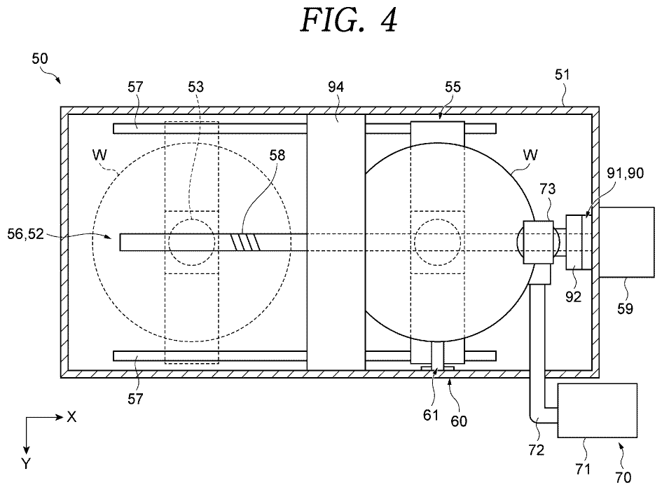

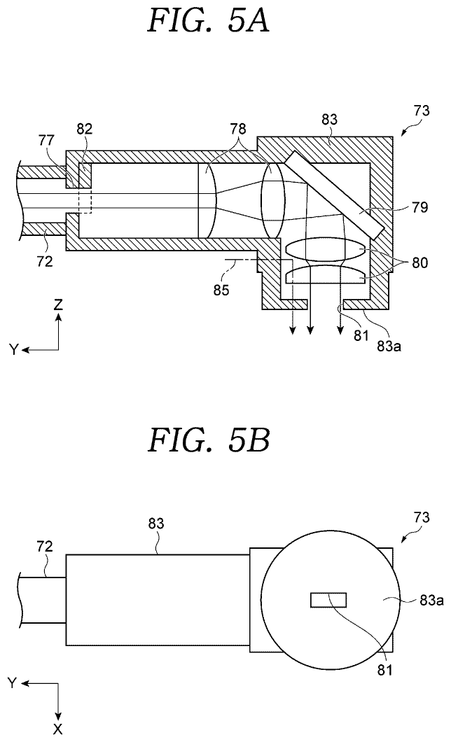

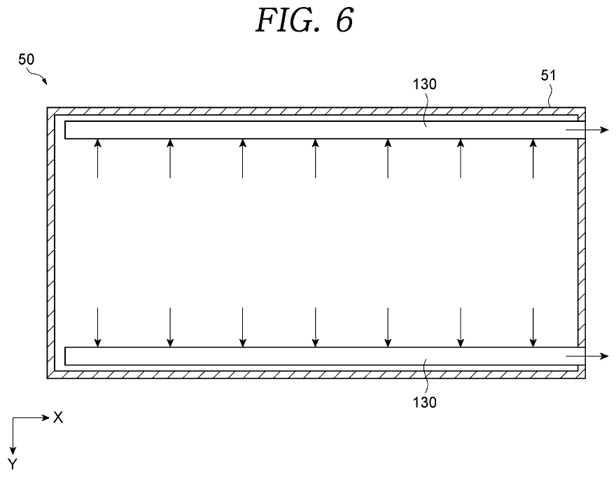

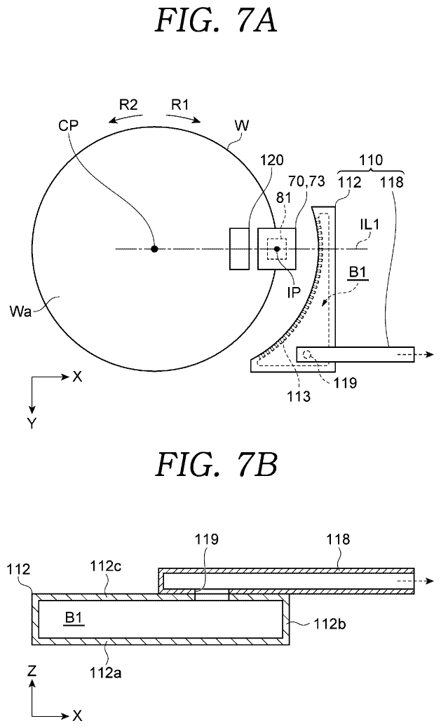

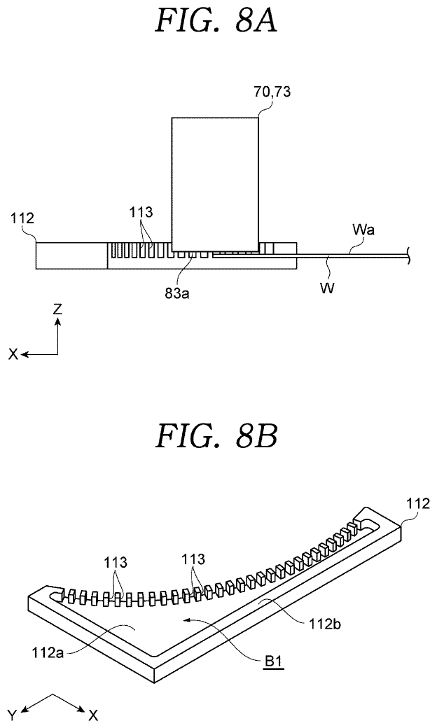

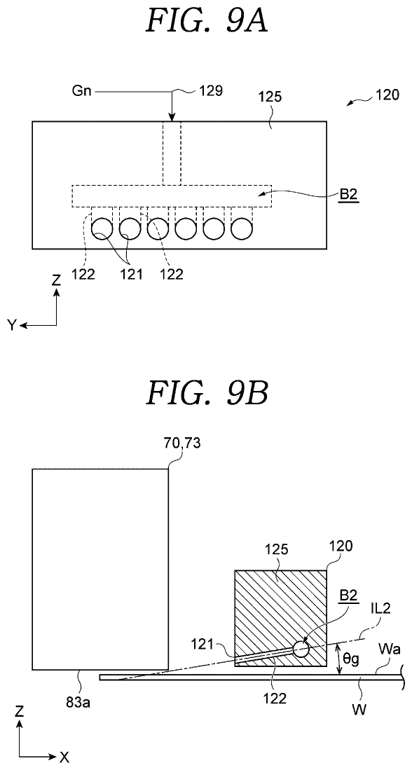

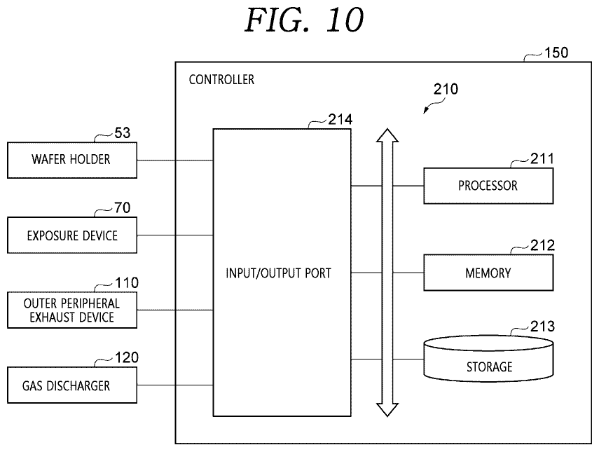

Hereinafter, an example of the edge exposure apparatus 50 of the wafer processing system 1 will be described with reference to FIG. 3 to FIG. 10. FIG. 3 is a side view including a partial cross-section of the edge exposure apparatus 50. FIG. 4 is a plan view including a partial section of the edge exposure apparatus 50. FIG. 5A and FIG. 5B are a longitudinal cross-sectional view and a bottom view, respectively, of a radiation device of the edge exposure apparatus 50. FIG. 6 is a plan view illustrating a lower exhaust device of the edge exposure apparatus 50. FIG. 7A is a plan view illustrating some members of the edge exposure apparatus 50. FIG. 7B is a longitudinal cross-sectional view of an outer peripheral exhaust device of the edge exposure apparatus 50. FIG. 8A and FIG. 8B are a side view and a perspective view, respectively, illustrating some members of the outer peripheral exhaust device. FIG. 9A and FIG. 9B are side views illustrating a gas discharger of the edge exposure apparatus 50. FIG. 10 is a block diagram illustrating a hardware structure of a controller of the edge exposure apparatus 50.

The edge exposure apparatus 50 is configured to perform an exposure processing on a peripheral region of a front surface (hereinafter, referred to as “front surface Wa”) of the wafer W. The peripheral region of the front surface Wa is an annular region including an edge of the front surface Wa and the vicinity thereof. The edge exposure apparatus 50 performs the exposure processing on the peripheral region of the front surface Wa of the wafer W to, for example, remove a peripheral portion of the resist film formed on the front surface Wa. As described above, the edge exposure apparatus 50 may function to expose the peripheral region of the front surface Wa of the wafer W on which the resist film has been formed, and also function to inspect the wafer W.

The edge exposure apparatus 50 includes a housing 51, a transfer device 52, an exposure device 70, and an inspection device 90. The housing 51 functions as a casing, and accommodates at least some of the members included in the edge exposure apparatus 50. The housing 51 may extend along the X-axis direction. A carry-in/out port 51a through which a carry-in/out of the wafer W is performed is provided at one end of the housing 51 in the X-axis direction. The wafer W is carried into the housing 51 and carried out of the housing 51 through the carry-in/out port 51a.

The transfer device 52 is configured to hold the wafer W, which is a processing target, and transfer the wafer W. The transfer device 52 includes, for example, a wafer holder 53 (substrate holder), a movement driver 55, and a sensor device 61.

The wafer holder 53 is configured to hold and rotate the wafer W. That is, the wafer holder 53 rotates the wafer W while holding the wafer W. The wafer holder 53 holds the wafer W such that the front surface Wa of the wafer W is horizontally flat, and rotates the wafer W about around the vertical axis. In an example, the wafer holder 53 includes a placing table 53a and a rotation driver 53b.

A back surface opposite to the front surface Wa of the wafer W is placed on the placing table 53a, and the placing table 53a holds the wafer W placed thereon. The placing table 53a may be placed in a lower space (for example, a lower half space) in the interior formed by the housing 51. The placing table 53a may hold the wafer W horizontally by absorption. The placing table 53a is provided rotatably and rotated around the vertical axis by the rotation driver 53b. The placing table 53a holds the wafer W such that a rotation axis of the rotation driver 53b substantially coincides with a center CP of the wafer W. Thus, the wafer W held by the placing table 53a is rotated by the rotation driver 53b around the vertical axis passing through the center CP of the wafer W or the vicinity thereof. The rotation driver 53b includes a driving source, such as an electric motor.

The movement driver 55 is configured to move the wafer holder 53 along one horizontal direction. In an example shown in FIG. 3, the movement driver 55 moves the wafer holder 53 along the X-axis direction. The movement driver 55 includes, for example, a ball screw mechanism 56 and a pair of guide rails 57 (see FIG. 4).

The ball screw mechanism 56 extends from the vicinity of one end of the housing 51 in the X-axis direction to the other end of the housing 51 in the X-axis direction at a bottom portion of the housing 51. The ball screw mechanism 56 includes a screw shaft 58 and a motor 59. The screw shaft 58 is a shaft member which is engaged with (screw-coupled to) the wafer holder 53 such that the wafer holder 53 can be moved in the X-axis direction. The motor 59 rotates the screw shaft 58 around an axis along the extension direction thereof.

The pair of guide rails 57 are provided with the ball screw mechanism 56 interposed therebetween in a direction (Y-axis direction) orthogonal to the extension direction (X-axis direction) of the ball screw mechanism 56. The guide rails 57 are disposed parallel to the ball screw mechanism 56. The guide rails 57 extend from the vicinity of one end of the housing 51 in the X-axis direction to the vicinity of the other end of the housing 51 in the X-axis direction at the bottom portion of the housing 51. The guide rails 57 support the wafer holder 53 to be movable.

As the motor 59 rotates the screw shaft 58, the wafer holder 53 (the placing table 53a and the rotation driver 53b) reciprocates along the X-axis direction. The movement driver 55 may include a cylinder mechanism or a belt mechanism, instead of the ball screw mechanism 56. The movement driver 55 can move the wafer holder 53 (the placing table 53a) between a first position P1 at one end of the housing 51 in the X-axis direction and a second position P2 at the other end of the housing 51 in the X-axis direction. The carry-in/out port 51a of the housing 51, the first position P1, and the second position P2 are arranged in sequence in the X-axis direction.

The sensor device 61 is configured to acquire information indicating rotational position of the wafer W held by the wafer holder 53. The sensor device 61 may function to detect an index portion (for example, a notch portion) indicating a reference position in a circumferential direction of the wafer W on the placing table 53a. The sensor device 61 includes, for example, a light emitting element 62 and a light receiving element 63. The edge of the wafer W on the placing table 53a is interposed vertically between the light emitting element 62 and the light receiving element 63 when the wafer holder 53 is located at the second position P2. The sensor device 61 detects the index portion, and the rotation driver 53b rotates the placing table 53a based on the detection result. Thus, a rotational position (angle) of the wafer W can be aligned.

The exposure device 70 is configured to radiate light for exposure (hereinafter, referred to as “exposure light”) toward the peripheral region of the front surface Wa of the wafer W held by the wafer holder 53. For example, while the wafer W is rotated by the rotation driver 53b in a state where the wafer holder 53 is located at the second position P2, the exposure device 70 radiates the exposure light toward the peripheral region of the front surface Wa of the wafer W. In an example, the exposure device 70 includes a light emitting member 71, a light guide member 72, and a light radiation member 73.

The light emitting member 71 includes a light source, and generates light for exposing the peripheral region of the front surface Wa. The light source included in the light emitting member 71 is, for example, an ultrahigh pressure mercury lamp. The light emitting member 71 may be provided outside the housing 51. The light guide member 72 is configured to connect the light emitting member 71 and the light radiation member 73 and guide the exposure light generated by the light emitting member 71 to the light radiation member 73. The light guide member 72 is, for example, an optical fiber.

The light radiation member 73 radiates the exposure light guided by the light guide member 72 toward the peripheral region of the front surface Wa of the wafer W. The light radiation member 73 includes, for example, a housing 83, an entry slit 77, an entry lens 78, a mirror 79, an exit lens 80, an exit slit 81, and a shutter 82 as shown in FIG. 5A and FIG. 5B. The housing 83 accommodates the entry lens 78, the mirror 79, the exit lens 80, and the shutter 82. Each of the entry slit 77 and the exit slit 81 is an opening formed in the housing 83.

The entry slit 77 has a rectangular shape, and regulates a cross-sectional shape of light flux when the light guided by the light guide member 72 is incident into the light radiation member 73 (into the housing 83). The shape of the light flux and the direction of the light incident into the housing 83 through the entry slit 77 are changed through the entry lens 78, the mirror 79, and the exit lens 80, and, thus, the light is guided to the exit slit 81.

The exit slit 81 is formed in a facing portion 83a of the housing 83. The facing portion 83a is oriented vertically downwards, and at least a part of the facing portion 83a faces the peripheral portion of the front surface Wa of the wafer W held by the wafer holder 53. The exit slit 81 has a rectangular shape, and regulates a cross-sectional shape of light flux when light passing through the exit lens 80 is emitted from the light radiation member 73 (from the inside to the outside of the housing 83).

The shutter 82 is configured to switch a state where the light from the light guide member 72 into the housing 83 is transmitted and a state where light from the light guide member 72 into the housing 83 is blocked. The shutter 82 may function to adjust an opening degree of the entry slit 77 when the light from the light guide member 72 into the housing 83 is transmitted. An open/closed state of the shutter 82 or the open/closed state and the opening degree may be controlled by a controller 150.

In the light radiation member 73, the exposure light guided by the light guide member 72 is emitted from the exit slit 81 to be radiated to a part of the peripheral region of the front surface Wa of the wafer W on which the resist film has been formed. In this state, as the rotation driver 53b rotates the wafer W, the exposure light can be radiated to the entire peripheral region of the front surface Wa of the wafer W (i.e., edge exposure).

The light radiation member 73 may include a gas discharger 85. The gas discharger 85 is configured to discharge an inert gas through one or more discharge openings (not shown) formed around the exit slit 81. The inert gas discharged from the gas discharger 85 is, for example, a nitrogen gas. The gas discharger 85 discharges the inert gas supplied into the housing 83 downwards through the one or more discharge openings formed around the exit slit 81. The gas discharger 85 is provided to reduce the amount of sublimates deposited on the facing portion 83a. Herein, the sublimates are generated from the resist film due to the radiation of the exposure light.

Referring back to FIG. 3 and FIG. 4, the inspection device 90 acquires information for inspection of the wafer W. The inspection device 90 includes an imaging device 91. The imaging device 91 is capable of imaging the front surface Wa of the wafer W. The imaging device 91 is located above the wafer W held by the transfer device 52 in the interior of the housing 51. The imaging device 91 includes, for example, a camera 92, a half mirror 93, and a lighting module 94.

In the interior of the housing 51, the camera 92 is fixed to a side wall opposite to a side wall in which the carry-in/out port 51a of the housing 51 is formed. The camera 92 is, for example, a CCD camera. The half mirror 93 and the lighting module 94 are provided near the center of the housing 51 in the X-axis direction. Light emitted from the lighting module 94 passes through the half mirror 93 so as to be radiated to below the half mirror 93. Reflection light from an object located below the half mirror 93 is reflected by the half mirror 93 to be incident into the camera 92. Thus, the camera 92 can image the object located below the half mirror 93 and radiated from the lighting module 94.

In the edge exposure apparatus 50, the imaging device 91 scans the front surface Wa of the wafer W on the placing table 53a while the wafer holder 53 moves along the guide rails 57 in the X-axis direction. The imaging device 91 may scan the front surface Wa while the wafer holder 53 (the wafer W) moves from the first position P1 to the second position P2 or from the second position P2 to the first position P1. The imaging device 91 may image the entire front surface Wa by scanning the front surface Wa while the wafer holder 53 moves between the first position P1 and the second position P2.

The edge exposure apparatus 50 is equipped with an outer peripheral exhaust device 110 (exhaust device) and a gas discharger 120. The outer peripheral exhaust device 110 performs exhaust from the outside of the edge of the wafer W held by the wafer holder 53 during at least an edge exposure period. The edge exposure period refers to a period during which the exposure device 70 radiates the exposure light toward the peripheral region of the front surface Wa of the wafer W in the state where the wafer W is rotated by the wafer holder 53. The gas discharger 120 discharges the inert gas from the inside of the edge of the wafer W toward a space between the light radiation member 73 of the exposure device 70 and the wafer W during at least the edge exposure period. The outer peripheral exhaust device 110 and the gas discharger 120 will be described below in more detail.

The edge exposure apparatus 50 includes a lower exhaust device 130. The lower exhaust device 130 located below the wafer W held by the wafer holder 53 exhausts the interior of the housing 51. The lower exhaust device 130 is located below the wafer W held by the wafer holder 53, and extends along the X-axis direction as shown in FIG. 6. The edge exposure apparatus 50 may include a pair of lower exhaust devices 130, and the pair of lower exhaust devices 130 may be located near a pair of side walls, respectively, of the housing 51 facing each other in the Y-axis direction.

A plurality of exhaust openings may be arranged along the X-axis direction in each of the pair of lower exhaust devices 130. A gas inside the housing 51 is discharged from the interior of the housing 51 to the outside of the housing 51 through the plurality of exhaust openings formed in the lower exhaust devices 130. Each of the pair of lower exhaust devices 130 may be connected to an exhaust pump via an exhaust line provided outside the housing 51.

FIG. 7A illustrates an example of a positional relationship among the wafer W held by the wafer holder 53 at the second position P2, the light radiation member 73 (the exit slit 81), the outer peripheral exhaust device 110, and the gas discharger 120 when viewed from the top. Hereinafter, the outer peripheral exhaust device 110 and the gas discharger 120 when the wafer holder 53 is located at the second position P2 will be described. The outer peripheral exhaust device 110 may perform exhaust from a predetermined exhaust range including a place corresponding a radiation position IP of the exposure device 70 and extending along the edge in an outside the edge of the wafer W held by the wafer holder 53.

The outer peripheral exhaust device 110 is located outside the edge of the wafer W held by the wafer holder 53 when viewed from the top. The radiation position IP of the exposure device 70 refers to a position where the exposure device 70 radiates the exposure light toward the peripheral region of the front surface Wa of the wafer W. The radiation position IP of the exposure device 70 may be defined as a certain position overlapping the exit slit 81 formed in the light radiation member 73 of the exposure device 70 when viewed from the top. For example, the radiation position IP of the exposure device 70 is a position of the center of the exit slit 81.

The place corresponding to the radiation position IP included in the exhaust range refers to a place which is located on a circumference around the center CP of the wafer W held by the wafer holder 53 and which intersects an imaginary line IL1 passing through the center CP and the radiation position IP. Herein, one way of a rotational direction of the wafer W rotated by the wafer holder 53 is defined as “rotational direction R1” and the other way is defined as “rotational direction R2”. The rotational direction R1 is clockwise and the rotational direction R2 is counter-clockwise when viewed from the top. In the present disclosure, the terms “upstream” and “downstream” are used based on the rotational direction R1 (one way). That is, when the wafer W is rotated in the rotational direction R1, a place (for example, the notch portion) at the edge of the wafer W continues from an upstream side toward a downstream side on the circumference around the center CP.

The outer peripheral exhaust device 110 may perform the exhaust from at least the place corresponding to the radiation position IP and the region at the downstream side of the place outside the edge of the wafer W held by the wafer holder 53. The exhaust range for the outer peripheral exhaust device 110 includes, for example, a first section at an upstream side of the place corresponding to the radiation position IP and a second section at a downstream side of the place corresponding to the radiation position IP. The second section may be greater than the first section.

The outer peripheral exhaust device 110 includes, for example, a collection member 112 and a suction member 118. The collection member 112 forms a plurality of exhaust openings 113 that defines the exhaust range and a buffer space B1 (exhaust buffer space) connected to the plurality of exhaust openings 113. As shown in FIG. 8A and FIG. 8B, the plurality of exhaust openings 113 is arranged along the edge of the wafer W held by the wafer holder 53. The plurality of exhaust openings 113 is spaced apart from each other. A range between the exhaust opening 113 located most upstream and the exhaust opening 113 located most downstream corresponds to the exhaust range. Also, a line in which the plurality of exhaust openings 113 is arranged need not be equal to the circumference around the center CP of the wafer W, and may be located on a circumference around a position different from the center CP (for example, a position near the center CP).

The sum of the opening areas of the one or more exhaust openings 113 located in the second section at the downstream side of the place corresponding to the radiation position IP may be greater than the sum of the opening areas of the one or more exhaust openings 113 located in the first section at the upstream side of the place corresponding to the radiation position IP. If the exhaust opening 113 is located at a boundary between the first section and the second section, some of the exhaust opening 113 located in the first section are added to the opening areas in the first section, and the other of the exhaust opening 113 located in the second section are added to the opening areas in the second section. In an example, the number of exhaust openings 113 located in the second section is greater than the number of exhaust openings 113 located in the first section.

As shown in FIG. 8A, the plurality of exhaust openings 113 may be located at the same height position in the vertical direction. As for one exhaust opening 113, a height position of at least a part of the exhaust opening 113 in the vertical direction may be equal to a height position of at least a part of the wafer W held by the wafer holder 53. A height position of at least a part of the wafer W in the vertical direction may be equal to a height position of at least a part of a lower half of the exhaust opening 113 or a height position of at least a part of an upper half of the exhaust opening 113. To further improve the collection efficiency of the sublimates, a height position of a region between the front surface Wa of the wafer W held by the wafer holder 53 and the facing portion 83a in the vertical direction may be equal to a height position of the vicinity of the center of the exhaust opening 113 in the vertical direction.

Unlike the example shown in FIG. 8A, a height position of the exhaust opening 113 in the vertical direction may be different from a height position of the wafer W held by the wafer holder 53. The exhaust opening 113 may be located above the wafer W or below the wafer W in the vertical direction. A distance (shortest distance) between the exhaust opening 113 and the wafer W in the vertical direction may be smaller than a size of the exhaust opening 113 in the vertical direction.

A height position of at least a part of the exhaust opening 113 in the vertical direction may be equal to a height position of the facing portion 83a in the light radiation member 73. Unlike the example shown in FIG. 8A, the exhaust opening 113 may be located above the facing portion 83a or below the facing portion 83a in the vertical direction. If the facing portion 83a is not flat, a height position of the facing portion 83a is defined as a height position of a lowermost portion (lowermost place) of the facing portion 83a.

The buffer space B1 may be enlarged in a first direction and a second direction along the front surface Wa of the wafer W held by the wafer holder 53. The first direction is a direction in which the imaginary line IL (line) passing through the center CP of the wafer W held by the wafer holder 53 and the radiation position IP of the exposure device 70 extends. The second direction is a direction orthogonal to the first direction. The first direction may be the X-axis direction and the second direction may be the Y-axis direction. Hereinafter, the first direction will be described as the X-axis direction and the second direction will be described as the Y-axis direction.

The collection member 112 includes a bottom portion 112a, a side wall 112b, and a top portion 112c. In FIG. 8A and FIG. 8B, illustration of the top portion 112c is omitted. The bottom portion 112a is formed into a plate shape, and a part of an edge of the bottom portion 112a is concave in a direction away from the center CP of the wafer W held by the wafer holder 53. Another part of the edge of the bottom portion 112a is formed straightly. The bottom portion 112a defines a lower surface of the buffer space B1.

The side wall 112b extends upwards from the edge of the bottom portion 112a and the vicinity thereof. The side wall 112b defines a lateral side of the buffer space B1. The plurality of exhaust openings 113 is formed in a portion of the side wall 112b corresponding to a part of the curved edge of the bottom portion 112a. The top portion 112c is connected to a top portion of the side wall 112b and defines an upper surface of the buffer space B1. The plurality of exhaust openings 113 formed in the side wall 112b connects the buffer space B1 to a space outside the buffer space B1. The plurality of exhaust openings 113 faces the edge of the wafer W held by the wafer holder 53 when viewed from the top.

The suction member 118 is configured to suction the inside of the buffer space B1 via a suction opening 119 opened to the buffer space B1. The suction member 118 is, for example, a cylindrical pipe. As shown in FIG. 7B, a bottom portion of the suction member 118 may overlap the top portion 112c of the collection member 112, and the suction opening 119 connecting the buffer space B1 and a flow path inside the suction member 118 may be formed in the overlap portion. In the suction member 118, an end of the pipe may be connected to the exhaust pump via an exhaust line provided outside the housing 51.

Since the suction member 118 suctions the inside of the buffer space B1, a gas inside the buffer space B1 is discharged to the outside of the housing 51 (the edge exposure apparatus 50). Accordingly, a gas around the exhaust openings 113 is introduced into the buffer space B1 via the plurality of exhaust openings 113. As described above, the outer peripheral exhaust device 110 performs the exhaust via the plurality of exhaust openings 113 and the buffer space B1. Since the outer peripheral exhaust device 110 performs the exhaust from the exhaust range around the edge of the wafer W, the sublimates generated from the resist film due to the radiation of the exposure light may be collected during the edge exposure period.

When viewed from a direction perpendicular to the front surface Wa of the wafer W held by the wafer holder 53 (viewed from vertically above), at least a part of the buffer space B1 decreases in size in the X-axis direction as a distance from the suction opening 119 in the Y-axis direction increases. That is, at least a part of the buffer space B1 decreases in size (space size) in the X-axis direction as a distance from the suction opening 119 in the Y-axis direction increases when the buffer space B1 is viewed from the suction opening 119.

In the example shown in FIG. 7A, a region between the imaginary line IL and the suction opening 119 in the buffer space B1 decreases in size in the X-axis direction as a distance from the suction opening 119 in the Y-axis direction increases. If the size of the buffer space B1 in the X-axis direction is uniform regardless of the position in the Y-axis direction, the exhaust opening 113 located adjacent to the suction opening 119 has a high exhaust rate, and the exhaust opening 113 located far from the suction opening 119 has a low exhaust rate. In this regard, a difference in exhaust rate caused by the distance from the suction opening 119 can be reduced by increasing a space adjacent to the suction opening 119 and decreasing a space far from the suction opening 119.

The radiation position IP and the suction opening 119 may be located between both ends of the buffer space B1 in the Y-axis direction. For the simplicity of explanation, one end of the buffer space B1 located on the left side of the radiation position IP when viewed from the center CP will be referred to as “upper end” and the other end located on the right side will be referred to as “lower end”. The upper end of the buffer space B1, the radiation position IP, the suction opening 119, and the lower end of the buffer space B1 are arranged in this order in the Y-axis direction.

The radiation position IP may be set to be closer to the upper end of the buffer space B1 in the Y-axis direction between the upper end (first end) and the lower end (second end) of the buffer space B1. That is, a distance (shortest distance) between the upper end of the buffer space B1 and the radiation position IP in the Y-axis direction may be smaller than a distance (shortest distance) between the lower end of the buffer space B1 and the radiation position IP in the Y-axis direction.

The suction opening 119 may be located closer to the lower end of the buffer space B1 in the Y-axis direction between the upper end and the lower end of the buffer space B1. That is, a distance (shortest distance) between the upper end of the buffer space B1 and the suction opening 119 in the Y-axis direction may be greater than a distance (shortest distance) between the lower end of the buffer space B1 and the suction opening 119 in the Y-axis direction. The suction opening 119 may be located near the lower end of the buffer space B1 in the Y-axis direction. For example, a distance between the suction opening 119 and the lower end of the buffer space B1 in the Y-axis direction is smaller than a distance between the suction opening 119 and the center of the buffer space B1 in the Y-axis direction.

The gas discharger 120 discharges an inert gas Gn from the inside of the edge of the wafer W held by the wafer holder 53 toward a space between the front surface Wa of the wafer W held by the wafer holder 53 and the facing portion 83a of the exposure device 70 facing the front surface Wa. When viewed from the top, the gas discharger 120 may be located on the imaginary line IL1 and is placed between the center CP and the radiation position IP. The gas discharger 120 may be fixed to the light radiation member 73 via a fixing member. The inert gas Gn discharged from the gas discharger 120 is, for example, a nitrogen gas. A discharge rate (discharge rate per unit time) of the gas from the gas discharger 120 may be higher than a discharge rate (discharge rate per unit time) of the gas from the gas discharger 85 in the light radiation member 73.

The gas discharger 120 includes, for example, a main body 125 and a plurality of discharge openings 121 as shown in FIG. 9A and FIG. 9B. The main body 125 has a block shape. The plurality of discharge openings 121 is formed in the main body 125 and configured to discharge the inert gas Gn. The plurality of discharge openings 121 is arranged in the Y-axis direction. The plurality of discharge openings 121 may have the same height position.

A buffer space B2 is charge buffer space) connected to the plurality of discharge openings 121 is formed within the main body 125. The buffer space B2 is connected to the plurality of discharge openings 121 via discharge paths 122, respectively. The gas discharger 120 is equipped with a gas supply 129 configured to supply the inert gas Gn to the buffer space B2. Since the inert gas Gn is supplied from the gas supply 129 to the buffer space B2, the inert gas Gn is discharged through the plurality of discharge openings 121.

The main body 125 is placed such that the plurality of discharge openings 121 faces the light radiation member 73 of the exposure device 70. At least some of the plurality of discharge openings 121 are formed such that the inert gas Gn discharged through the discharge openings 121 flows through a region between the facing portion 83a and the front surface Wa of the wafer W held by the wafer holder 53 to the outside of the wafer W. A distance between the facing portion 83a and the front surface Wa of the wafer W held by the wafer holder 53 in the vertical direction may be from 0.2 mm to 2.0 mm, from 0.25 mm to 1.8 mm, or from 0.3 mm to 1.5 mm.

Each of the plurality of discharge openings 121 may be formed to discharge the inert gas Gn obliquely downwards. The discharge paths 122 connecting the buffer space B2 and the discharge openings 121, respectively, may extend obliquely downwards from the buffer space B1.

An angle (hereinafter, referred to as “discharge angle θg”) in a direction of discharging the inert gas Gn through the discharge opening 121 toward the front surface Wa of the wafer W held by the wafer holder 53 may be 5° or more, 5.5° or more, 6° or more, or 6.5° or more to array the main body 125 to be spaced apart from the front surface Wa. If the discharge angle θg is smaller than 5°, the main body 125 is likely to be in contact with the front surface Wa of the wafer W held by the wafer holder 53 due to a component tolerance.

The discharge angle θg may be 15° or less, 14.5° or less, 14° or less, or 13.5° or less to facilitate the flow of the inert gas Gn discharged through the discharge opening 121 toward the outside of the edge of the wafer W. If the discharge angle θg is greater than 15°, it may be difficult for the inert gas Gn through the discharge opening 121 to flow toward the outside of the edge of the wafer W. In an example, the discharge angle θg is from 5° to 15° or from 6.5° to 13.5°.

As for at least one of the plurality of discharge openings 121, the discharge angle θg may be measured as an angle between an imaginary line IL2 and the front surface Wa of the wafer W held by the wafer holder 53. The imaginary line IL2 is an imaginary line passing through the center of the discharge opening 121 and extending in an extension direction of the discharge path 122 connected to the discharge opening 121. The imaginary line IL2 may pass through a space between the facing portion 83a and the front surface Wa of the wafer W held by the wafer holder 53. Accordingly, the inert gas Gn is discharged toward the space from the discharge opening 121.

Referring back to FIG. 3, the edge exposure apparatus 50 includes the controller 150. The controller 150 controls various components of the edge exposure apparatus 50. The controller 150 may be a computer separate from the control device 100 of the wafer processing system 1.

The controller 150 may control the exposure device 70 to radiate the exposure light while the wafer W is rotated in the rotational direction R1 by the wafer holder 53 at least in a state where the exhaust is continued by the outer peripheral exhaust device 110. In addition, the controller 150 may control the exposure device 70 to radiate the exposure light while the wafer W is rotated in the rotational direction R2 by the wafer holder 53 in a state where the exhaust is continued by the outer peripheral exhaust device 110.

As shown in FIG. 10, the controller 150 includes, for example, a circuit 210. The circuit 210 includes a processor 211, a memory 212, a storage 213, and an input/output port 214. The storage 213 is composed of one or more non-volatile memory devices, such as a flash memory or a hard disk. The storage 213 stores therein programs for controlling the apparatus to implement a process of holding and rotating the wafer W by the wafer holder 53, a process of radiating the exposure light, by the exposure device 70, toward the peripheral region of the front surface Wa of the wafer W held by the wafer holder 53, and a process of performing the exhaust, by the outer peripheral exhaust device 110, from the exhaust range including the place corresponding to the radiation position IP outside the edge of the wafer W held by the wafer holder 53 and extending along the edge. The storage 213 functions as a program storage.

The memory 212 is composed of one or more volatile memory devices, such as a random access memory (RAM). The memory 212 temporarily stores a program loaded from the storage 213. The processor 211 is composed of one or more arithmetic devices, such as a central processing unit (CPU) or a graphics processing unit (GPU). The processor 211 controls various components of the edge exposure apparatus 50 by executing the program loaded in the memory 212. The result of the operation by the processor 211 is temporarily stored in the memory 212. The input/output port 214 inputs and outputs information among the wafer holder 53, the exposure device 70, the outer peripheral exhaust device 110, and the gas discharger 120 in response to a demand from the processor 211.

Various functions of the controller 150 may be executed by a dedicated logic circuit or an application specific integrated circuit (ASIC) instead of the programs. The controller 150 may be configured by a plurality of computers that is communicably connected to each other. The controller 150 may a component of the control device 100 provided in the wafer processing system 1. The control device 100 may include the same circuit as the circuit 210 shown in FIG. 10.

### Edge Exposure Method

Hereinafter, an edge exposure method performed by the edge exposure apparatus 50 will be described. The edge exposure method may include a process of holding and rotating the wafer W by means of the wafer holder 53, a process of irradiating exposure light toward a peripheral region of the front surface Wa of the wafer W held by the wafer holder 53, and a process of performing exhaust from an exhaust range including a place corresponding to the radiation position IP of exposure light outside an edge of the wafer W held by the wafer holder 53 and extending along the edge.

The edge exposure method may include a process of holding and rotating the wafer W in the rotational direction R1 by means of the wafer holder 53, a process of irradiating exposure light toward a peripheral region of the front surface Wa of the wafer W held by the wafer holder 53, and a process of performing exhaust, by means of the outer peripheral exhaust device 110, from at least a place corresponding to the radiation position IP of exposure light outside an edge of the wafer W held by the wafer holder 53 and a region at the downstream side of the place based on the rotational direction R1. Further, in the edge exposure method, the exposure light may be emitted toward the peripheral region while the wafer W is rotated in the rotational direction R1 by the wafer holder 53 in a state where exhaust is continued by the outer peripheral exhaust device 110.

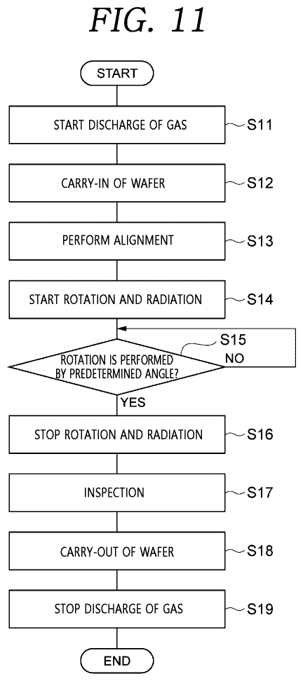

FIG. 11 shows a series of processes implemented by the controller 150 when an edge exposure processing and an inspection processing are performed on a single wafer W. In the series of processes, the controller 150 performs a process S11 in a state where the wafer holder 53 is located at the first position P1 and the exhaust is continued by the outer peripheral exhaust device 110 and the lower exhaust device 130. While the following series of processes are performed, the exhaust is continued by the outer peripheral exhaust device 110 and the lower exhaust device 130. In the process S11, for example, the controller 150 starts the discharge of the inert gas Gn from the gas discharger 120 and the discharge of the inert gas from the gas discharger 85 in the light radiation member 73 of the exposure device 70.

Then, the controller 150 performs processes S12 and S13. In the process S12, for example, the controller 150 controls the wafer transfer device 33 and the wafer holder 53 to carry the wafer W, which is the processing target, into the housing 51. In the process S13, for example, the controller 150 controls the movement driver 55 to move the wafer holder 53 from the first position P1 to the second position P2. Also, the controller 150 controls the sensor device 61 to detect the index portion of the wafer W and controls the wafer holder 53 to align the posture of the wafer W such that the index portion is located at a predetermined angular position.

Thereafter, the controller 150 performs processes S14 and S15. In the process S14, for example, the controller 150 starts the rotation of the wafer W by the wafer holder 53 and the radiation of the exposure light by the exposure device 70. Thus, the exposure light is radiated toward the peripheral region of the front surface Wa of the wafer W. The controller 150 may control the rotation driver 53b to rotate the wafer W in the rotational direction R1. In the process S15, for example, the controller 150 waits until the wafer W is rotated by a predetermined angle. The predetermined angle may be 360° or more in order to expose the entire peripheral region of the front surface Wa of the wafer W.

Then, the controller 150 performs a process S16. In the process S16, for example, the controller 150 stops the rotation of the wafer W by the wafer holder 53 and the radiation of the exposure light by the exposure device 70. Until the process S16 is completed, the exposure light is radiated toward the peripheral region of the front surface Wa of the wafer W and the sublimates are generated from the resist film formed on the front surface Wa. Since the exhaust is continued by the outer peripheral exhaust device 110, the sublimates generated from the resist film may be collected by the outer peripheral exhaust device 110. When the sublimates flow to below the wafer W, the sublimates can be collected by the lower exhaust device 130.

Thereafter, the controller 150 performs a process S17. In the process S17, for example, the controller 150 controls the movement driver 55 to move the wafer holder 53 from the second position P2 to the first position P1. The controller 150 controls the imaging device 91 of the inspection device 90 to image the front surface Wa of the wafer W while the wafer holder 53 is moved to the first position P1. The controller 150 may output image data acquired from the imaging device 91 to the control device 100.

Then, the controller 150 performs processes S18 and S19. In the process S18, for example, the controller 150 controls the wafer holder 53 and the wafer transfer device 33 to carry the wafer W out of the housing 51. In the process S19, for example, the controller 150 stops the discharge of the inert gas Gn from the gas discharger 120 and the discharge of the inert gas from the gas discharger 85 in the light radiation member 73 of the exposure device 70.

The controller 150 may repeat the above-described series of processes composed of the processes S11 to S19 for each of a plurality of subsequent wafers W. When the controller 150 performs the series of processes for some of the plurality of subsequent wafers W, the wafer holder 53 may rotate the wafer W in the rotational direction R2 in the processes S14 to S16.

### Modification Example

The series of processes shown in FIG. 11 are just examples and may be modified appropriately. In the series of processes, the controller 150 may perform one process and the next process in parallel, or may perform the individual processes in an order different from that in the above-described examples. The controller 150 may omit any one of the processes, or may perform a processing different from that described above in any one of the processes.

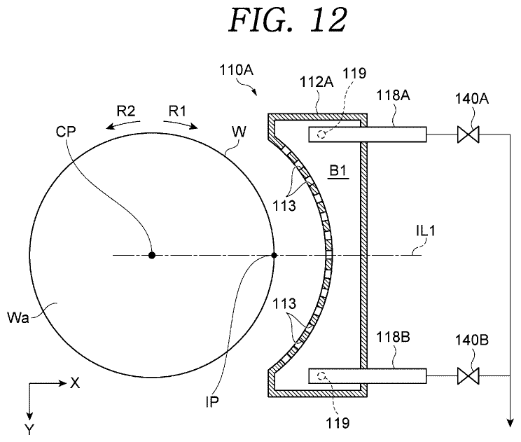

As shown in FIG. 12, the edge exposure apparatus 50 may be equipped with an outer peripheral exhaust device 110A instead of the outer peripheral exhaust device 110. The outer peripheral exhaust device 110A includes a collection member 112A, a suction member 118A, and a suction member 118B. The buffer space B1 formed by the collection member 112A may be line-symmetrical with respect to the imaginary line IL1 when viewed from the top. In FIG. 12, illustration of a top portion of the collection member 112A is omitted.

The plurality of exhaust openings 113 formed in the collection member 112A may also be line-symmetrical with respect to the imaginary line IL1 when viewed from the top. The sum of the opening areas of one or more exhaust openings 113 located in a section at the upstream side of the place corresponding to the radiation position IP among the plurality of exhaust openings 113 formed in the collection member 112A may be substantially equal to the sum of the opening areas of one or more exhaust openings 113 located in a section at the downstream side of the place corresponding to the radiation position IP.

The suction opening 119 formed in the suction member 118A and opened to the buffer space B1 may be located near the upper end of the buffer space B1 in the Y-axis direction. The suction opening 119 formed in the suction member 118B and opened to the buffer space B1 may be located near the lower end of the buffer space B1 in the Y-axis direction.

The edge exposure apparatus 50 includes an opening/closing member 140A and an opening/closing member 140B. The opening/closing member 140A is provided in a flow path connected to the suction member 118A and configured to switch on and off suction by the suction member 118A. The opening/closing member 140B is provided in a flow path connected to the suction member 118B and configured to switch on and off suction by the suction member 118B. The opening/closing member 140A and the opening/closing member 140B are, for example, dampers or valves.

When the edge exposure is performed while rotating the wafer W in the rotational direction R1, the controller 150 may control the opening/closing member 140A and the opening/closing member 140B to switch off the suction by the suction member 118A and switch on the suction by the suction member 118B. When the edge exposure is performed while rotating the wafer W in the rotational direction R2, the controller 150 may control the opening/closing member 140A and the opening/closing member 140B to switch on the suction by the suction member 118A and switch off the suction by the suction member 118B.

When the edge exposure is performed while the wafer W is rotated by the wafer holder 53, the controller 150 may control the opening/closing member 140A and the opening/closing member 140B to switch on the suction by the suction member 118A and switch on the suction by the suction member 118B regardless of the rotation direction of the wafer W.

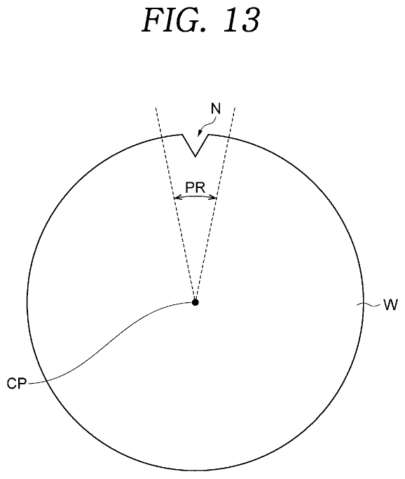

As shown in FIG. 13, a notch portion N as the index portion may be formed at the edge of the wafer W. In this case, when the exposure light is radiated to a predetermined range including the notch portion N, the controller 150 may change the exhaust rate (exhaust rate per unit time) of the outer peripheral exhaust device 110. In this case, the outer peripheral exhaust device 110 is configured to regulate the exhaust rate. The controller 150 may control the outer peripheral exhaust device 110 such that an exhaust rate during a period in which the exposure light from the exposure device 70 is radiated toward a predetermined range PR including the notch portion N is higher than an exhaust rate during a period in which the exposure light from the exposure device 70 is radiated outside the predetermined range PR.

The predetermined range PR in which the exhaust rate is increased refers to a range of positions (angles) in the circumferential direction around the center CP, and may be a range of angles corresponding only to the notch portion N or may be a range of angles corresponding to the notch portion N and the vicinity thereof as shown in FIG. 13. When one end of the predetermined range PR reaches the radiation position IP due to the rotation of the wafer W, the controller 150 may change the exhaust rate of the outer peripheral exhaust device 110 from a first exhaust rate to a second exhaust rate which is higher than the first exhaust rate. After the exhaust rate is changed to the second exhaust rate, when the other end of the predetermined range PR reaches the radiation position IP due to the rotation of the wafer W, the controller 150 may change the exhaust rate of the outer peripheral exhaust device 110 from the second exhaust rate to the first exhaust rate. Except for the two places where the exhaust rate is changed, the controller 150 may maintain the current exhaust rate of the outer peripheral exhaust device 110.

When the exposure light is radiated toward the predetermined range PR including the notch portion N, the controller 150 may change a discharge rate (discharge rate per unit time) of the gas from the gas discharger 120 instead of or as well as the exhaust rate of the outer peripheral exhaust device 110. In this case, the gas discharger 120 (or the gas supply 129) is configured to regulate the discharge rate. The controller 150 may control the gas discharger 120 such that a discharge rate during a period in which the exposure light from the exposure device 70 is radiated toward the predetermined range PR including the notch portion N is higher than a discharge rate during a period in which the exposure light from the exposure device 70 is radiated outside the predetermined range PR.

When one end of the predetermined range PR reaches the radiation position IP due to the rotation of the wafer W, the controller 150 may change the discharge rate of the gas discharger 120 from a first discharge rate to a second discharge rate which is higher than the first discharge rate. After the discharge rate is changed to the second discharge rate, when the other end of the predetermined range PR reaches the radiation position IP due to the rotation of the wafer W, the controller 150 may change the discharge rate of the gas discharger 120 from the second discharge rate to the first discharge rate. Except for the two places where the discharge rate is changed, the controller 150 may maintain the current discharge rate of the gas discharger 120.

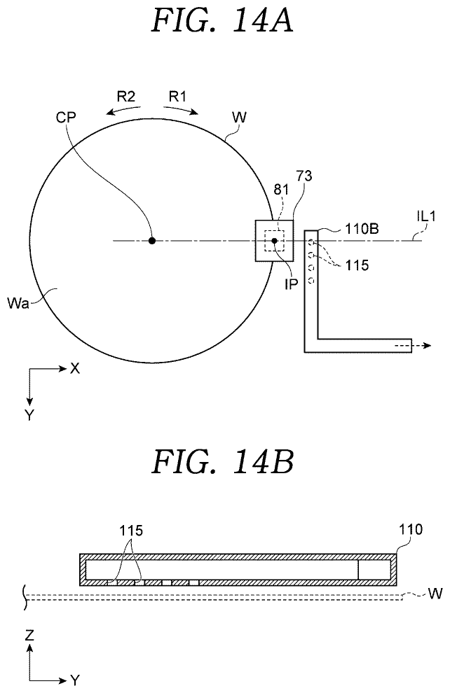

To perform the exhaust from the place corresponding to the radiation position IP and the region at the downstream side of the place based on the rotational direction R1, the exhaust range for the outer peripheral exhaust device of the edge exposure apparatus 50 may not follow the edge of the wafer W. As shown in FIG. 14A and FIG. 14B, the edge exposure apparatus 50 may be equipped with an outer peripheral exhaust device 110B instead of the outer peripheral exhaust device 110. The outer peripheral exhaust device 110B is a pipe configured to guide the exhaust gas to the outside of the housing 51.

At least a part of the outer peripheral exhaust device 110B may extend along the Y-axis direction, and a plurality of exhaust openings 115 is formed in a bottom portion of the part extending along the Y-axis direction. The plurality of exhaust openings 115 is arranged along the Y-axis direction. At least some of the plurality of exhaust openings 115 are located at the downstream side of the place corresponding to the radiation position IP. The sum of the opening areas of the exhaust openings 115 located at the downstream side of the place corresponding to the radiation position IP among the plurality of exhaust openings 115 may be smaller than the sum of the opening areas of the exhaust openings 115 located at the upstream side of the place corresponding to the radiation position IP. Even when the outer peripheral exhaust device 110B is provided in the edge exposure apparatus 50, the controller 150 may perform the series of processes shown in FIG. 11.

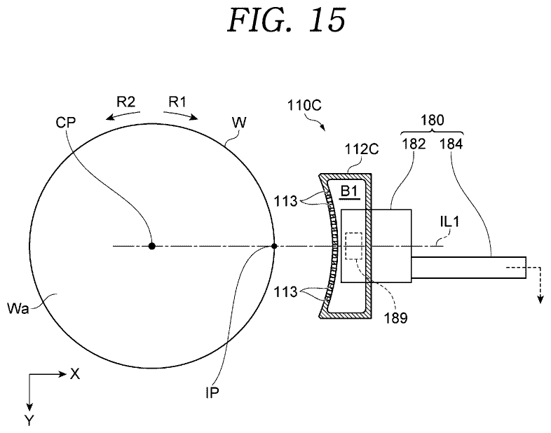

As shown in FIG. 15, the edge exposure apparatus 50 may be equipped with an outer peripheral exhaust device 110C instead of the outer peripheral exhaust device 110. The outer peripheral exhaust device 110C includes a collection member 112C and a suction member 180. The buffer space B1 formed by the collection member 112C is enlarged in the X-axis direction and the Y-axis direction like the buffer space B1 formed by the collection member 112 and the buffer space B1 formed by the collection member 112A. When viewed from the direction perpendicular to the front surface Wa of the wafer W held by the wafer holder 53 (viewed from vertically above), the buffer space B1 of the collection member 112C is line-symmetrical with respect to the imaginary line IL1. The buffer space B1 of the collection member 112C may have a substantially uniform size in the vertical direction.

A width of the buffer space B1 of the collection member 112C in the Y-axis direction is smaller than a width of the wafer W in the Y-axis direction. The width of the buffer space B1 in the Y-axis direction is defined as a distance (shortest distance) between the upper end and the lower end of the buffer space B1 in the Y-axis direction. The width of the wafer W in the Y-axis direction is equivalent to, for example, a diameter of the wafer W. The width of the buffer space B1 of the collection member 112C in the Y-axis direction may be ⅘ or less, ¾ or less, or ⅔ or less of the width of the wafer W in the Y-axis direction. The width of the buffer space B1 of the collection member 112C in the Y-axis direction may be greater than a radius of the wafer W or smaller than the radius of the wafer W. The width of the buffer space B1 of the collection member 112C in the Y-axis direction may be ⅓ or more, ¼ or more, or ⅕ or more of the width of the wafer W in the Y-axis direction.

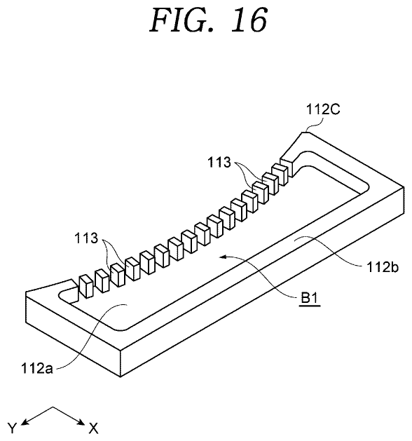

FIG. 16 shows a perspective view of the collection member 112C. In FIG. 15 and FIG. 16, illustration of the top portion 112c of the collection member 112C is omitted. The plurality of exhaust openings 113 formed in the collection member 112C may also be line-symmetrical with respect to the imaginary line IL1 when viewed from the top. The sum of the opening areas of one or more exhaust openings 113 located in a section at the upstream side of the place corresponding to the radiation position IP among the plurality of exhaust openings 113 formed in the collection member 112C may be substantially equal to the sum of the opening areas of one or more exhaust openings 113 located in a section at the downstream side of the place corresponding to the radiation position IP.

The suction member 180 suctions the inside of the buffer space B1 via a suction opening 189 opened to the buffer space B1. When viewed from the direction perpendicular to the front surface Wa of the wafer W held by the wafer holder 53 (viewed from vertically above), the suction opening 189 is located on the imaginary line IL1. When viewed from the top, the suction opening 189 may be line-symmetrical with respect to the imaginary line IL1. In this case, a distance (shortest distance) between the upper end of the buffer space B1 and the suction opening 189 in the Y-axis direction may be substantially equal to a distance (shortest distance) between the lower end of the buffer space B1 and the suction opening 189 in the Y-axis direction.

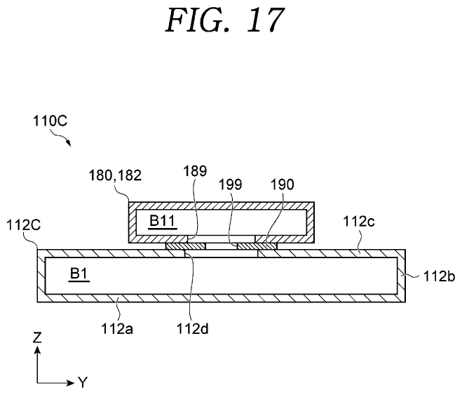

The suction member 180 includes an exhaust block 182 and an exhaust pipe 184. The exhaust block 182 is located at a position overlapping the collection member 112C, and an exhaust buffer space (hereinafter, referred to as “buffer space B11”, see FIG. 17) is connected to the buffer space B1 via the suction opening 189. The exhaust pipe 184 is a pipe of which one end is connected to the exhaust block 182 and which is configured to guide a gas from the inside of the buffer space B11 to the outside of the housing 51. The exhaust pipe 184 may be a curved cylindrical pipe.

As shown in FIG. 17, the outer peripheral exhaust device 110C may include an adjusting member 190. The adjusting member 190 is configured to adjust a flow rate of a gas flowing from the buffer space B1 to the buffer space B11. A bottom portion of the exhaust block 182 overlaps the top portion 112c of the collection member 112C via the adjusting member 190. That is, the collection member 112C, the adjusting member 190, and the exhaust block 182 are arranged in this order from the bottom. An opening 112d is formed in the top portion 112c of the collection member 112C, and an edge of the opening 112d may substantially coincide with an edge of the suction opening 189 when viewed from the top.

The adjusting member 190 may be formed into, for example, a plate shape. An opening 199 is formed in a thickness direction of the adjusting member 190. The opening 199 may have a smaller size than the suction opening 189. The flow rate (exhaust rate) of the gas flowing from the buffer space B1 to the buffer space B11 is defined by the size of the opening 199. The adjustment of the flow rate of the gas by the adjusting member 190 implies changing the flow rate of the gas in a case where the adjusting member 190 is not provided, by the opening 199 which is smaller in size than the suction opening 189 (or the opening 112d). In the edge exposure apparatus 50 equipped with the outer peripheral exhaust device 110C, it may be difficult to change the size of the suction opening 189 or the. Even in this case, the exhaust rate can be adjusted by the opening 199 of the adjusting member 190.

When the adjusting member 190 is not provided, the exhaust block 182 may overlap the collection member 112C so as to be in contact with the top portion 112c of the collection member 112C. Even when the outer peripheral exhaust device 110C is provided, the controller 150 may perform the series of processes shown in FIG. 11.

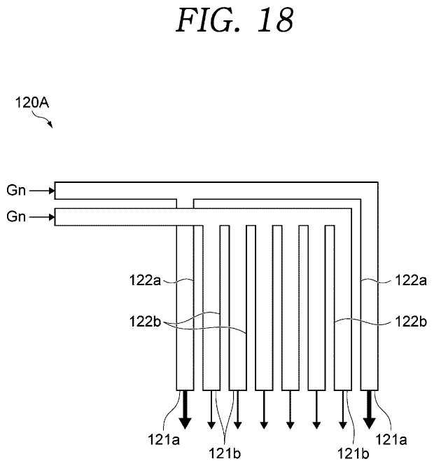

The edge exposure apparatus 50 may include a gas discharger 120A instead of the gas discharger 120. FIG. 18 is a schematic view of the gas discharger 120A, and shows a plurality of discharge openings of the gas discharger 120A and a plurality of flow paths connected to the plurality of discharge openings. Like the gas discharger 120, the gas discharger 120A discharges the inert gas Gn from the inside of the edge of the wafer W held by the wafer holder 53 toward the space between the front surface Wa of the wafer W held by the wafer holder 53 and the facing portion 83a of the exposure device 70 facing the front surface Wa.

Each of a pair of discharge openings 121 respectively formed at both ends among the plurality of discharge openings 121 is referred to as “discharge opening 121a” and the other discharge openings 121 are referred to as “discharge openings 121b”. The gas discharger 120A is configured such that a discharge rate (discharge rate per unit time) of each of the pair of discharge openings 121a is higher than a discharge rate of each discharge opening 121b. Flow paths 122a connected to the pair of discharge openings 121a, respectively, and flow paths 122b connected to the respective discharge openings 121b may be connected to different buffer spaces (buffer spaces for discharge). By increasing the discharge rate of each of the pair of discharge openings 121a, the amount of sublimates scattered to the outside of the pair of discharge openings 121a can be reduced.

The edge exposure apparatus 50 may not have the function of performing the inspection processing, but may have the function of performing the edge exposure. Each of the outer peripheral exhaust devices 110, 110A and 110C may be provided with one opening or two or more openings extending along the edge of the wafer W instead of the plurality of exhaust openings 113 arranged along the edge of the wafer W. The outer peripheral exhaust device 110B may be provided with one opening or two or more openings extending along the Y-axis direction instead of the plurality of exhaust openings 115 arranged along the Y-axis direction.

In one example among the various examples described above, at least a part of the matters described in another example may be combined.

### Summary of Present Disclosure

The present disclosure includes the configurations or methods described in the following paragraphs [1] to [16].

[1] An edge exposure apparatus 50 includes: a substrate holder 53 configured to hold and rotate a substrate W; an exposure device 70 configured to radiate exposure light toward a peripheral region of a front surface of the substrate W held by the substrate holder 53; and an exhaust device 110, 110A or 110C configured to perform exhaust from an exhaust range including, in an outside of an edge of the substrate held by the substrate holder, a place corresponding to a radiation position IP of the exposure device 70 and extending along the edge.

In the edge exposure apparatus 50, the exhaust device 110, 110A or 110C can perform the exhaust from the exhaust range extending along the edge of the substrate W while the substrate W is rotated and the peripheral region of the front surface Wa of the substrate W is exposed. As the substrate W is rotated, the sublimates generated due to the radiation of the exposure light can be scattered along the edge of the substrate W. For this reason, the edge exposure apparatus 50 can efficiently collect the sublimates as compared to the case where the exhaust is performed through one place at the edge of the substrate W. Therefore, it is useful for suppressing the deposition of the sublimates onto the substrate W, which is the subsequent processing target.

[2] In the edge exposure apparatus 50 described in paragraph [1], the exhaust device 110, 110A or 110C includes multiple exhaust openings 113 arranged along the edge and an exhaust buffer space B1 connected to the multiple exhaust openings 113. The exhaust device 110, 110A or 110C performs exhaust via the plurality of exhaust openings 113 and the buffer space B1 for exhaust.

In this case, the exhaust device 110, 110A or 110C and a member connected thereto can be simplified as compared to a case where a flow path for exhaust is provided for each of the plurality of exhaust openings 113. Therefore, it is useful for collecting the sublimates efficiently and simplifying the apparatus.

[3] In the edge exposure apparatus 50 described in paragraph [2], the exhaust device 110, 110A or 110C further includes a suction member 118, 118A, 118B or 180 configured to suction an inside of the exhaust buffer space B1 via a suction opening 119 or 189 opened to the exhaust buffer space B1.

In this case, even when a buffer space is provided within the edge exposure apparatus 50, the suction member 118, 118A, 118B or 180 can discharge a gas to the outside of the edge exposure apparatus 50.

[4] In the edge exposure apparatus 50 described in paragraph [3], the exhaust buffer space B1 is enlarged in a first direction and a second direction along the front surface Wa of the substrate W held by the substrate holder 53. The first direction is a direction in which a line IL1 passing through a center CP of the substrate W held by the substrate holder 53 and the radiation position IP of the exposure device 70 extends. The second direction is a direction orthogonal to the first direction. When viewed from a direction perpendicular to the front surface of the substrate W held by the substrate holder 53, at least a part of the exhaust buffer space B1 decreases in size in the first direction as a distance from the suction opening 119 in the second direction increases.

In this case, as described above, a difference between the multiple exhaust openings 113 in exhaust rate caused by the distance from the suction opening 119 can be reduced.

[5] In the edge exposure apparatus 50 described in paragraph [2], the exhaust buffer space B1 is enlarged in a first direction and a second direction along the front surface Wa of the substrate W held by the substrate holder 53. The first direction is a direction in which a line IL1 passing through a center CP of the substrate W held by the substrate holder 53 and the radiation position IP of the exposure device 70 extends. The second direction is a direction orthogonal to the first direction. When viewed from a direction perpendicular to the front surface of the substrate W held by the substrate holder 53, the exhaust buffer space B1 is line-symmetrical with the line IL1.

In this case, the amount of sublimates collected by the collection member 112C which forms the buffer space B1 may be equal in the rotational direction R1 which is one way of rotation of the substrate W by the substrate holder 53 and in the rotational direction R2 which is the other way of rotation. Thus, the non-uniformity in processing caused by the difference in rotation direction can be reduced.

[6] In the edge exposure apparatus 50 described in paragraph [5], the exhaust device 110C further includes a suction member 180 configured to suction an inside of the exhaust buffer space B1 via a suction opening 189 opened to the exhaust buffer space B1. When viewed from a direction perpendicular to the front surface Wa of the substrate W held by the substrate holder 53, the suction opening 189 is located on the line IL1.

The radiation position IP of the exposure device 70 is located on the line IL1 by its definition. It is found that the amount of sublimates generated at the radiation position IP is greater than that in the other places. In the above-described configuration, the suction opening 189 is located on the line IL1, and, thus, the exhaust is strongly performed from a place close to the radiation position IP in the exhaust range. Thus, the sublimates can be efficiently collected.

[7] In the edge exposure apparatus 50 described in paragraph [5] or [6], a width of the exhaust buffer space B1 in the second direction is smaller than a width of the substrate W in the second direction.

Various members in addition to the exhaust device 110C may be provided within the edge exposure apparatus 50. In the above-described configuration, the exhaust buffer space B1 is located to allow the line IL1 to pass therethrough. Thus, it is possible to efficiently collect the sublimates from the place where the sublimates are most likely to be generated, and also possible to suppress the interference between the outer peripheral exhaust device 110C and the other members.

[8] In the edge exposure apparatus 50 described in paragraph [2], the exhaust device 110 or 110A further includes a suction member 118, 118A or 118B configured to suction an inside of the exhaust buffer space B1 via a suction opening 119 opened to the exhaust buffer space B1. The exhaust buffer space B1 is enlarged in a first direction and a second direction along the front surface Wa of the substrate W held by the substrate holder 53. The first direction is a direction in which a line IL1 passing through a center CP of the substrate W held by the substrate holder 53 and the radiation position IP of the exposure device 70 extends. The second direction is a direction orthogonal to the first direction. The radiation position IP of the exposure device 70 is set to be closer, between a first end (upper end) and a second end (lower end) of the exhaust buffer space B1, to the first end (upper end) of the exhaust buffer space B1 in the second direction, and the suction opening 119 is located closer to the second end (lower end) in the second direction between the first end (upper end) and the second end (lower end).

In this case, it is easy to suppress the interference between the suction member 118 including the suction opening 119 and the exposure device 70 configured to radiate the exposure light.

[9] An edge exposure apparatus 50 includes: a substrate holder 53 configured to hold and rotate a substrate W; an exposure device 70 configured to radiate exposure light toward a peripheral region of a front surface Wa of the substrate W held by the substrate holder 53; an exhaust device 110, 110A, 110B or 110C configured to perform exhaust from at least a place corresponding to a radiation position IP of the exposure device 70 and a region at a downstream side of the place in an outside of an edge of the substrate W held by the substrate holder 53, when the substrate W is rotated in one direction by the substrate holder 53; and a controller 150 configured to control the exposure device 70 to emit the exposure light while the substrate W is rotated in the one direction R1 by the substrate holder 53 in a state where the exhaust is continued by the exhaust device 110, 110A, 110B or 110C.

In the edge exposure apparatus 50, when the edge exposure is performed while rotating the substrate W in the one direction R1, the exhaust is performed from the position at the downstream side of the place corresponding to the radiation position IP by the exhaust device 110, 110A, 110B or 110C. As the substrate W is rotated in the one direction R1, the sublimates generated due to the radiation of the exposure light can also be further scattered to the downstream side in the one direction R1. For this reason, the edge exposure apparatus 50 can efficiently collect the sublimates as compared to the case where the exhaust is not performed from the position at the downstream side of the place corresponding to the radiation position IP. Therefore, it is useful for suppressing the deposition of the sublimates onto the substrate W, which is the subsequent processing target.

[10] The edge exposure apparatus 50 described in any one of paragraphs [1] to [9] further includes: a gas discharger 120 or 120A configured to discharge an inert gas Gn from an inside of the edge of the substrate W held by the substrate holder 53 toward a space between the front surface Wa of the substrate W held by the substrate holder 53 and a facing portion 83a of the exposure device 70 facing the front surface Wa of the substrate W.

In this case, the sublimates generated due to the radiation of the exposure light from the exposure device 70 can be moved by the inert gas Gn to the outside of the edge of the wafer W. Since the exhaust device 110, 110A, 110B or 110C is provided outside the edge of the wafer W, the amount of sublimates collected by the exhaust device can be increased. Therefore, the sublimates can be more efficiently collected.

[11] In the edge exposure apparatus 50 described in paragraph [10], the gas discharger 120 includes multiple discharge openings 121 and a discharge buffer space B1 connected to the multiple discharge openings 121.

Since the inert gas Gn is discharged through the discharge openings, the gas can be more strongly discharged even at the same discharge rate. For this reason, the sublimates can be further moved to the outside of the edge of the substrate W. Thus, it is possible to efficiently collect the sublimates.

[12] In the edge exposure apparatus 50 described in paragraph or [11], an angle θg in a direction of discharging the inert gas Gn from the discharge openings 122 of the gas discharger 120 with respect to the front surface Wa of the substrate W held by the substrate holder 53 is from 5° to 15°.

As described above, when the angle θg is smaller than 5°, the main body of the gas discharger 120 is likely to be in contact with the front surface Wa of the substrate W. Meanwhile, when the angle θg is greater than 15°, the sublimates may not be moved by the inert gas Gn to the outside of the edge of the substrate W. Since the angle θg is set to be from 5° to 15°, such likelihood can be reduced. Also, when the distance between the facing portion 83a and the front surface Wa is further decreased, it is more useful to set the angle θg to be from 5° to 15°.

[13] The edge exposure apparatus 50 described in any one of paragraphs [1] to [8] further includes: a controller 150, and a notch portion N is formed at the edge of the substrate W. The controller 150 controls the exhaust device 110, 110A, 110B or 110C such that an exhaust rate during a period in which the exposure light from the exposure device 70 is radiated toward a predetermined range PR including the notch portion N is higher than an exhaust rate during a period in which the exposure light from the exposure device 70 is radiated outside the predetermined range PR.

The amount of resist may be greater in the notch portion N than in other places. In this case, a greater amount of sublimates may be generated in the notch portion N. In the above-described configuration, when the predetermined range PR including the notch portion N is exposed, the exhaust rate of the exhaust device 110, 110A or 110B is increased. Thus, it is possible to suppress the increase in the amount of sublimates generated due to the notch portion N.

[14] The edge exposure apparatus 50 described in any one of paragraphs [1] to [8] further includes: a gas discharger 120 configured to discharge an inert gas Gn from an inside of the edge of the substrate W held by the substrate holder 53 toward a space between the front surface Wa of the substrate W held by the substrate holder 53 and a facing portion 83a of the exposure device 70 facing the front surface Wa of the substrate W; and a controller 150. The notch portion N is formed at the edge of the substrate W. The controller 150 controls the gas discharger 120 such that a discharge rate during a period in which the exposure light from the exposure device 70 is radiated toward a predetermined range PR including the notch portion N is higher than a discharge rate during a period in which the exposure light from the exposure device 70 is radiated outside the predetermined range PR.

The amount of resist may be greater in the notch portion N than in other places. In this case, a greater amount of sublimates may be generated in the notch portion N. In the above-described configuration, when the predetermined range PR including the notch portion N is exposed, the discharge rate of the gas from the gas discharger 120 is increased. Thus, it is possible to suppress the increase in the amount of sublimates generated due to the notch portion N.

[15] An edge exposure method includes: holding and rotating a substrate W by a substrate holder 53; radiating exposure light toward a peripheral region of a front surface Wa of the substrate W held by the substrate holder 53; and performing exhaust from an exhaust range including, in an outside of an edge of the substrate held by the substrate holder, a place corresponding to a radiation position IP of the exposure light and extending along the edge.

Like the edge exposure apparatus 50 described in paragraph [1], the edge exposure method is useful for suppressing the deposition of the sublimates onto the substrate W, which is a subsequent processing target.

[16] An edge exposure method includes: holding and rotating a substrate W in an one direction R1 by a substrate holder 53; radiating exposure light toward a peripheral region of a front surface of the substrate W held by the substrate holder 53; and performing exhaust, by the exhaust device 110, 110A, 110B or 110C, from at least a place corresponding to a radiation position IP of the exposure light and a region at the downstream side of the place in an outside of an edge of the substrate W held by the substrate holder 53, based on the one direction R1. Further, the exposure light is emitted toward the peripheral region while the substrate W is rotated in the one direction R1 by the substrate holder 53 in a state where the exhaust is continued by the exhaust device 110, 110A, 110B or 110C.

According to the present disclosure, there are provided the edge exposure apparatus and the edge exposure method capable of suppressing the deposition of the sublimates onto the substrate, which is the subsequent processing target.

Like the edge exposure apparatus 50 described in paragraph [9], the edge exposure method is useful for suppressing deposition of the sublimates onto the substrate W, which is a subsequent processing target.

We claim:

1. An edge exposure apparatus, comprising:
a substrate holder configured to hold and rotate a substrate;
an exposurer configured to radiate exposure light toward a peripheral region of a front surface of the substrate held by the substrate holder; and
an exhaust positioned outside of an edge of the substrate held by the substrate holder, the exhaust configured to perform exhaust from a place corresponding to a radiation position of the exposurer and extending along the edge of the substrate.

2. The edge exposure apparatus of claim 1, wherein
the exhaust includes:
multiple exhaust openings arranged along the edge of the substrate; and
an exhaust buffer space connected to the multiple exhaust openings, and
the exhaust performs the exhaust via the multiple exhaust openings and the exhaust buffer space.

3. The edge exposure apparatus of claim 2, wherein the exhaust further includes a suction member configured to suction an inside of the exhaust buffer space via a suction opening opened to the exhaust buffer space.

4. The edge exposure apparatus of claim 3, wherein
the exhaust buffer space extends in a first direction and a second direction along the front surface of the substrate held by the substrate holder,
the first direction is defined by a line passing through a center of the substrate held by the substrate holder and the radiation position of the exposurer,
the second direction is a direction orthogonal to the first direction, and
when viewed from a direction perpendicular to the front surface of the substrate held by the substrate holder, at least a part of the exhaust buffer space decreases in size in the first direction as a distance from the suction opening in the second direction increases.

5. The edge exposure apparatus of claim 2, wherein
the exhaust buffer space extends in a first direction and a second direction along the front surface of the substrate held by the substrate holder,
the first direction is defined by a line passing through a center of the substrate held by the substrate holder and the radiation position of the exposurer,
the second direction is a direction orthogonal to the first direction, and
when viewed from a direction perpendicular to the front surface of the substrate held by the substrate holder, the exhaust buffer space is line-symmetrical with the line.

6. The edge exposure apparatus of claim 5, wherein the exhaust further includes a suction member configured to suction an inside of the exhaust buffer space via a suction opening opened to the exhaust buffer space, and
when viewed from the direction perpendicular to the front surface of the substrate held by the substrate holder, the suction opening is located on the line.

7. The edge exposure apparatus of claim 5, wherein a width of the exhaust buffer space in the second direction is smaller than a width of the substrate in the second direction.

8. The edge exposure apparatus of claim 2, wherein
the exhaust further includes a suction member configured to suction an inside of the exhaust buffer space via a suction opening opened to the exhaust buffer space,
the exhaust buffer space extends in a first direction and a second direction along the front surface of the substrate held by the substrate holder,
the first direction is defined by a line passing through a center of the substrate held by the substrate holder and the radiation position of the exposurer,
the second direction is a direction orthogonal to the first direction,
the radiation position of the exposurer is set to be closer, between a first end and a second end of the exhaust buffer space, to the first end of the exhaust buffer space in the second direction, and
the suction opening is located closer to the second end in the second direction between the first end and the second end.

9. The edge exposure apparatus of claim 1, wherein the exposurer includes a light emitter member, a light guide, and a light radiator.

10. The edge exposure apparatus of claim 9, wherein the light radiator includes a housing, an entry slit, an entry lens, a mirror, an exit lens, an exit slit, and a shutter.

11. The edge exposure apparatus of claim 1, further comprising:
a gas discharger configured to discharge an inert gas from an inside of the edge of the substrate held by the substrate holder toward a space between the front surface of the substrate held by the substrate holder and a facing portion of the exposurer facing the front surface of the substrate.

12. The edge exposure apparatus of claim 11, wherein the gas discharger includes multiple discharge openings and a discharge buffer space connected to the multiple discharge openings.

13. The edge exposure apparatus of claim 11, wherein an angle in a direction of discharging the inert gas from a discharge opening of the gas discharger with respect to the front surface of the substrate held by the substrate holder is from 5° to 15°.

14. The edge exposure apparatus of claim 1, further comprising:
circuitry,
wherein a notch portion is formed at the edge of the substrate, and
the circuitry controls the exhaust such that an exhaust rate during a period in which the exposure light from the exposurer is radiated toward a predetermined range including the notch portion is higher than an exhaust rate during a period in which the exposure light from the exposurer is radiated outside the predetermined range.

15. The edge exposure apparatus of claim 1, further comprising:
a gas discharger configured to discharge an inert gas from an inside of the edge of the substrate held by the substrate holder toward a space between the front surface of the substrate held by the substrate holder and a facing portion of the exposurer facing the front surface of the substrate; and
circuitry,
wherein a notch portion is formed at the edge of the substrate, and
the circuitry controls the gas discharger such that a discharge rate during a period in which the exposure light from the exposurer is radiated toward a predetermined range including the notch portion is higher than a discharge rate during a period in which the exposure light from the exposurer is radiated outside the predetermined range.

16. An edge exposure apparatus, comprising:
a substrate holder configured to hold and rotate a substrate;
an exposurer configured to radiate exposure light toward a peripheral region of a front surface of the substrate held by the substrate holder;
an exhaust configured to perform exhaust from at least a place corresponding to a radiation position of the exposurer and a region at a downstream side of the place in an outside of an edge of the substrate held by the substrate holder, when the substrate is rotated in one direction by the substrate holder; and
circuitry configured to control the exposurer to emit the exposure light while the substrate is rotated in the one direction by the substrate holder in a state where the exhaust continues to perform exhaust.

17. The edge exposure apparatus of claim 16, wherein the exposurer includes a light emitter member, a light guide, and a light radiator.

18. The edge exposure apparatus of claim 17, wherein the light radiator includes a housing, an entry slit, an entry lens, a mirror, an exit lens, an exit slit, and a shutter.

19. An edge exposure method, comprising:
holding and rotating a substrate by a substrate holder;
radiating, via an exposurer, exposure light toward a peripheral region of a front surface of the substrate held by the substrate holder; and
performing exhaust from an outside of an edge of the substrate held by the substrate holder, a place corresponding to a radiation position of the exposure light and extending along the edge.

20. The edge exposure method of claim 19, wherein the exposurer includes a light emitter member, a light guide, and a light radiator, and
wherein the light radiator includes a housing, an entry slit, an entry lens, a mirror, an exit lens, an exit slit, and a shutter.
